(19) United States
(12) Patent Application Publication
(10) Pub. No.: US 2026/0182374 A1
(43) Pub. Date: Jun. 25, 2026

(54) THERMAL MANAGEMENT SYSTEM FOR USE IN MICROGRID INTERCONNECT DEVICE

(71) Applicant: EATON INTELLIGENT POWER LIMITED, DUBLIN 4 (IE)

(72) Inventors: Ravi Sidhpuria, Surat (IN); Ankit Bhagat, Raipur (IN); Amit Chavan, Kolhapur (IN); Mahesh Ighe, Pune (IN)

(73) Assignee: EATON INTELLIGENT POWER LIMITED, DUBLIN 4 (IE)

(21) Appl. No.: 18/989,152

(22) Filed: Dec. 20, 2024

(51) Int. Cl. H01L 23/38; H01L 23/427

(52) U.S. Cl. CPC H10W 40/28; H10W 40/73

(57) ABSTRACT

A thermal management system for use in a microgrid interconnect device includes a cooling devices connected to metering ICs and structured to maintain metering IC temperature below maximum metering IC operational temperature, a heatsink device structured to absorb and dissipate heat from the metering ICs, temperature sensors structured to measure ambient air temperature near the metering ICs and metering IC temperature; and a power supply and controller connected to the cooling devices, the temperature sensors and the primary power source, the power supply and controller being structured to receive signals from the temperature sensors and cause the cooling devices to lower the metering IC temperature below the maximum metering IC operational temperature based on a signal indicating that the ambient air temperature is higher than the maximum metering IC operational temperature.

### FIELD OF THE INVENTION:

The disclosed concept relates generally to an islanding device, and in particular, to a microgrid interconnect device (MID) including a thermal management system for actively cooling metering ICs in the MID.

### BACKGROUND OF THE INVENTION:

Solar energy, or photovoltaic (PV) systems coupled with energy storage systems have increasingly become an alternative to diesel generators for back-up power for single-family residences, multi-family residences, or small commercial or industrial businesses. These PV inverters, and energy storage battery inverters (collectively referred to as distributed energy resources (DERs)) are each connected to an electrical main panel, which interfaces with a primary power source (e.g., without limitation, utility grid (hereinafter, also referred to as the grid)) and draws power from this connection to power normal loads and to charge vehicles or batteries.

A microgrid is a localized group of the DERs and loads and operate independently from the grid during the islanded mode or conjunction with the grid in the grid-connected mode. Islanding is the ability to disconnect from the grid in the event of, e.g., without limitation, a power outage while retaining the ability to manage the DERs and the loads. A microgrid interconnect device (MID) is a device structured to facilitate the connection and disconnection (islanding) of the microgrid from the grid. It ensures that the microgrid can operate in both the grid-connected and islanded modes while maintaining the safety and reliability of the electrical system. An MID is typically connected at the point of common coupling, which serves as a boundary between the DERs and the grid. Conventionally, an MID is installed as a separate panel and connected to an existing power panel (e.g., without limitation, a meter breaker panel), which includes a meter breaker and branch circuit breakers. As such, in order to install a conventional MID, extensive rewiring is required to connect the meter breaker to the MID and then connect the MID to the branch circuit breakers. Installing an additional MID and resultant extensive rewiring is costly and requires substantial time, resources and space that are already limited. In response, a minimized MID that can be retrofit within the existing panel has been developed.

As shown in FIGS. 1-3, a minimized MID 20 is disposed within the meter breaker panel 2 between the meter breaker 3 and the branch circuit breakers 4. Such a minimized MID 20 is compact so as to be easily retrofittable in the existing meter breaker panels 2, thereby eliminating the extensive rewiring and reducing the additional costs, time and spaces required for installing the conventional MID panels. A minimized MID 20 includes a housing 22, a switching element such as a relay, a control circuit, a communication circuit and a measurement circuit (e.g., without limitation, sensing circuit printed circuit board (PCB)) 200. Upon detection of a power loss, the relay is turned OFF, and thus the MID 20 disconnects the DERs from the grid and allows the DERs to supply power to the loads. Upon detection of the presence of grid power and synchronization of the voltages and frequencies of the grid and the DERs, the MID 20 reconnects the DERs and the grid and allows both the grid and the DERs to supply power to the loads. In some examples, the DERs supply to the grid any excessive power generated by them in the grid-connected mode.

In general, the voltage is tapped at inputs (L1 and L2) of the grid and the DERs and the voltage tapped is brought to the sensing circuit PCB 200 through wire harness. As shown in FIGS. 3 and 4, the sensing circuit PCB 200 includes Rogowski coil 210, a current transformer and metering integrated chips (ICs) 220. The metering ICs 220 are disposed below the relay and structured to measure 3-phase electrical energy using shunts as current sensors. They support current transformers and Rogowski coil (di/dt) sensors, provide multiple range phase/gain compensation for the current transformers and include a digital integrator for Rogowski coils 210. The metering ICs 220 have operating temperature ranging, e.g., without limitation, from −40° C. to +85° C. At steady-state, the metering ICs 200 receive heat from the branch circuit breakers 4 and the relay. However, due to the compact structure, a minimized MID 20 presents thermal challenges in the meter breaker. That is, the metering IC 220 may be exposed to high ambient temperature beyond the maximum metering IC operational temperature (e.g., without limitation, +8˜85° C.) 221 as shown in FIG. 5. For example, it has been observed through thermal tests and simulations that the air proximate to a metering IC 220 can be as hot as 105° C., when the meter breaker 3 operates at its highest rated current and the atmospheric temperature is at the maximum operational temperature (e.g., without limitation, 50° C.) of the MID 20. In such cases, the metering ICs 220 may stop operating beyond the maximum metering IC operational temperature. However, the metering ICs 220 must operate continuously since they communicate with the DERs constantly, Thus, the metering ICs operation failure results in failure to measure the 3-phase electrical energy and renders the MID 20 ineffective.

There is room for improvement in the islanding devices, in particular the MIDs.

### SUMMARY OF THE INVENTION:

These needs, and others, are met by a thermal management system for use in a microgrid interconnect device (MID). The MID has a housing, a relay structured to connect or disconnect a distributed energy resource from a primary power source, and a sensing circuit printed circuit board (PCB) including metering integrated chips (IC) structured to measure three-phase electrical energy. The thermal management system includes a plurality of cooling devices connected to the metering ICs and structured to maintain metering IC temperature below maximum metering IC operational temperature, a heatsink device connected to the cooling devices and structured to absorb and dissipate heat from the metering ICs, a plurality of temperature sensors including ambient air temperature sensors and metering IC temperature sensors, the ambient air temperature sensors disposed proximate the metering ICs on the sensing circuit PCB and structured to measure the ambient air temperature, the metering IC temperature sensors disposed on the metering ICs and structured to measure the metering IC temperature; and a power supply and controller connected to the cooling devices, the temperature sensors and the primary power source, the power supply and controller being structured to receive signals from the temperature sensors and cause the cooling devices to lower the metering IC temperature below the maximum metering IC operational temperature based on a signal indicating that the ambient air temperature is higher than the maximum metering IC operational temperature.

Another example embodiment provides a microgrid interconnect device (MID) structured to connect or disconnect a distributed energy resource (DER) from a primary power source. The MID includes: a housing having a front casing and a back casing; a relay disposed in the front casing and structured to connect or disconnect the DER from the primary power source; a sensing circuit printed circuit board (PCB) including metering integrated chips (IC) structured to measure three-phase electrical energy; and a thermal management system. The thermal management system includes: a plurality of cooling devices connected to the metering ICs and structured to maintain metering IC temperature below maximum metering IC operational temperature; a heatsink device connected to the cooling devices and structured to absorb and dissipate heat from the metering ICs; a plurality of temperature sensors including ambient air temperature sensors and metering IC temperature sensors, the ambient air temperature sensors disposed proximate the metering ICs on the sensing circuit PCB and structured to measure the ambient air temperature, the metering IC temperature sensors disposed on the metering ICs and structured to measure the metering IC temperature; and a power supply and controller connected to the cooling devices, the temperature sensors and the primary power source, the power supply and controller being structured to receive signals from the temperature sensors and cause the cooling devices to lower the metering IC temperature below the maximum metering IC operational temperature based on a signal indicating that the ambient air temperature is higher than the maximum metering IC operational temperature.

### BRIEF DESCRIPTION OF THE DRAWINGS:

A full understanding of the invention can be gained from the following description of the preferred embodiments when read in conjunction with the accompanying drawings in which:

FIG. 1 illustrates an exemplary meter breaker panel including an exemplary microgrid interconnect device (MID);

FIG. 2 is a perspective view of the MID of FIG. 1;

FIG. 3 is the interior view of the MID including a sensing circuit printed circuit board (PCB) disposed in the MID of FIG. 2;

FIG. 4 is the sensing circuit PCB including metering ICs of FIG. 3;

FIG. 5 illustrates failure points of a metering IC;

FIG. 6 is an exploded front view of an MID including an exemplary novel thermal management system in accordance with a non-limiting example embodiment of the disclosed concept;

FIG. 7 is an exploded front view of an MID including another exemplary novel thermal management system in accordance with a non-limiting example embodiment of the disclosed concept; and

FIG. 8 illustrates a partial MID including another exemplary thermal management system in accordance with a non-limiting example embodiment of the disclosed concept.

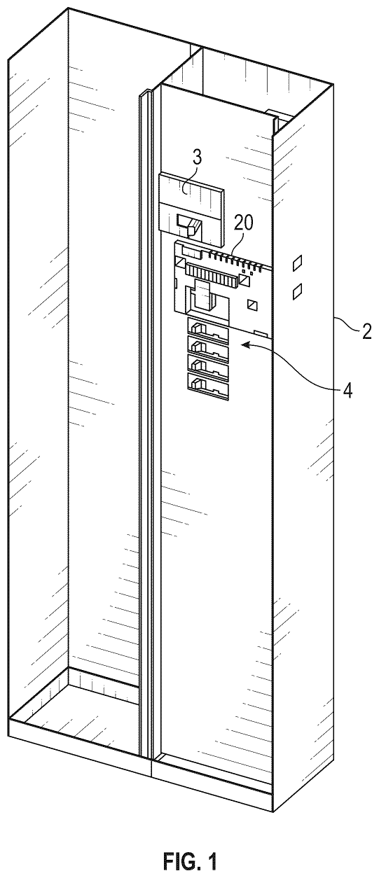

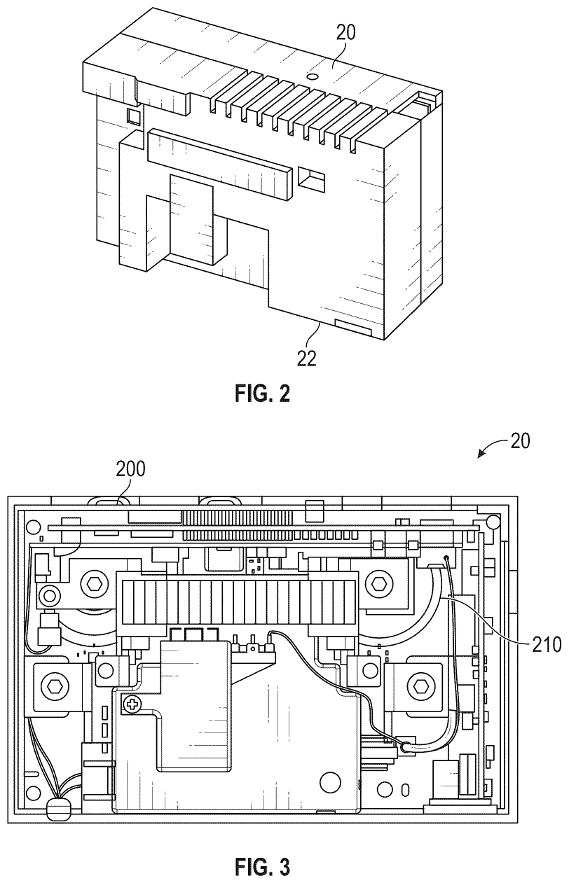

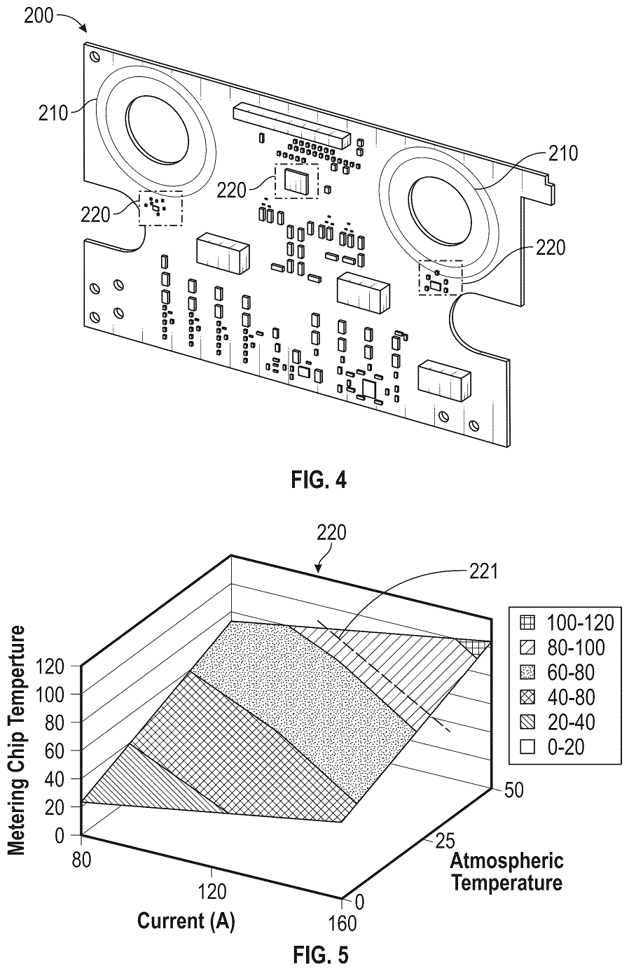

### DETAILED DESCRIPTION OF THE INVENTION:

Directional phrases used herein, such as, for example, left, right, front, back, top, bottom and derivatives thereof, relate to the orientation of the elements shown in the drawings and are not limiting upon the claims unless expressly recited therein.

As employed herein, the statement that two or more parts are “coupled” together shall mean that the parts are joined together either directly or joined through one or more intermediate parts.

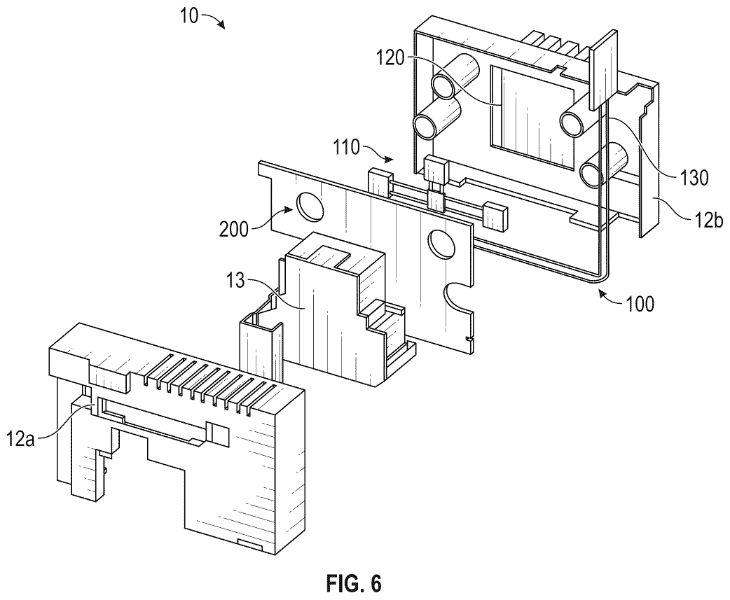

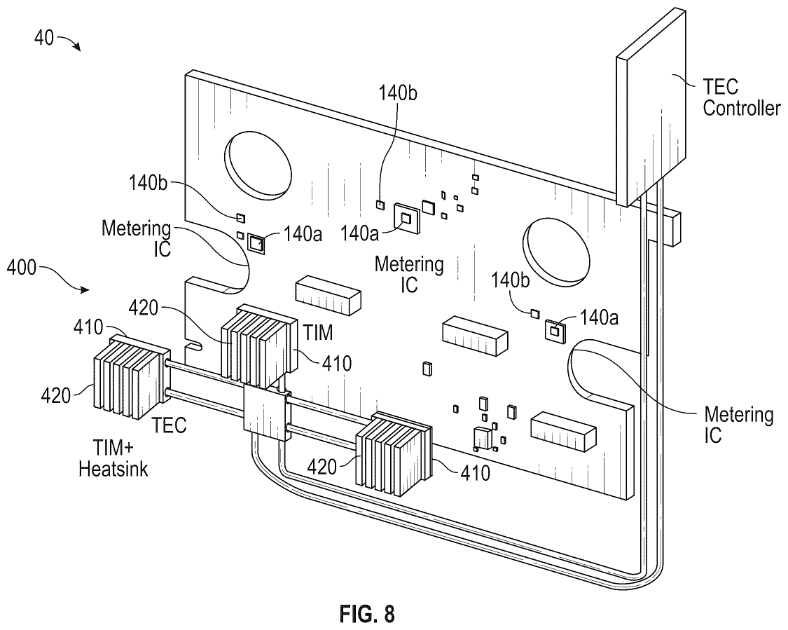

FIG. 6 is an exploded front view of an exemplary microgrid interconnect device (MID) 10 in accordance with a non-limiting, example embodiment of the disclosed concept. The MID 10 similar to the MID 20, and thus overlapping description is omitted for the sake of brevity. The MID 10 includes a housing, a relay 13, a sensing circuit printed circuit board (PCB) 200 and a novel thermal management system 100. The housing includes a front casing 12a and a back casing 12b. The back casing 12b includes a slot (e.g., without limitation, a square slot) 12c. The thermal management system 100 includes a plurality of cooling devices 110, a heatsink device 120, a power supply and controller 130 and temperature sensors 140a, 140b (as shown in FIG. 8). The cooling devices 110 are structured to maintain the metering IC temperature within the minimum (e.g., without limitation, −40° C.) and maximum (e.g., without limitation, 85° C.) operational temperature limits. Specifically, the cooling devices 110 cools the metering ICs 220 below their surrounding air temperature during peak loads and temperatures.

The cooling devices 110 may be, e.g., without limitation, Peltier coolers. A Peltier cooler is also known as thermoelectric cooler (TEC). It is a solid-state heat pump that transfers heat from one side to the other, depending on the direction of the electric current. Peltier effect refers to the phenomenon in which heat is either absorbed or released when an electric current flows across a junction of two different types of materials. A Peltier cooler in general utilizes pairs of p-type and n-type semiconductor materials, and when a DC voltage is applied, heat is moved from one side (the cold side) to the other (the hot side). It is used for various applications, even when active cooling below ambient temperature or high temperature precision (stability<0.01° C.) is required as here. A Peltier cooler is available with a maximum operation temperature of 200° C., which is defined by the reflow temperature of a solder and sealing. Small designs can be realized using TECs and there are no moving parts. A Peltier cooler may have a size of 1 mm×1 mm up to 60 mm×60 mm.

Referring back to FIG. 6, each Peltier cooler 110 has a hot side and a cold side, and is structured to be attached to respective metering ICs 220 on the cold side and to a heatsink device 120 on the hot side using, e.g., without limitation, a thermal interface material (TIM). The heatsink device 120 includes a single heatsink 120 disposed on the external surface of the back casing 12b and structured to be attached to the hot side of the Peltier cooler 110 through the slot 12c. The temperature sensors comprise the metering IC temperature sensors 140a disposed on respective metering ICs 220 and the ambient air temperature sensors 140b disposed proximate to the metering ICs 220 on the sensing circuit PCB 200. The metering IC temperature sensors 140a detect the instantaneous temperature of the metering ICs 220 and the ambient air temperature sensors 140b detect the temperature of the ambient air proximate to the metering ICs 220. The temperature sensors 140a, 140b transmit signals indicating the instantaneous ambient air temperature and the instantaneous metering IC temperature to the power supply and controller 130. The power supply and controller 130 is disposed outside of the housing of the MID 10 and connected to the temperature sensors 140a, 140b, the Peltier coolers 110, and a main line (e.g., without limitation, a primary power source line). It is structured to receive signals from the temperature sensors 140a, 140b and control the Peltier coolers 110 based on the signals. It controls the Peltier coolers 110 by applying DC voltage, thereby causing the heat to move from the cold side to the hot side. The power supply and controller 130 is structured to harvest power to operate the Peltier coolers 110 from the main line only during the peak loads and temperatures. As such, a close-loop system is formed by the Peltier coolers 110, the temperature sensors 140a, 140b and the power supply and controller 130. Power consumption by the Peltier coolers 110 is thus controlled through the close-loop system, which takes feedback from the temperature sensors 140a, 140b and the power supply and controller 130.

In operation, upon receiving a signal indicating that the proximate air temperature is higher than the maximum IC operational temperature, the power supply and controller 130 causes the Peltier coolers 110 to lower the metering IC temperatures below the maximum metering IC operational temperature. That is, the power supply and controller 130 applies DC voltage to the Peltier coolers 110 and causes the heat to move from the cold side to the hot side. The heatsink 120 then absorbs and dissipates the heat, thereby cooling the metering ICs 220. For example, for a metering IC 220 having a size of 30 mm³, density of 3,900 Kg/m³ and specific heat capacity Cp of 880 J/Kg ° C., if the maximum ambient temperature proximate the metering IC 220 is, e.g., without limitation, 105° C. and the maximum metering IC operational temperature is, e.g., without limitation, 85° C., then the maximum heat removal Qc to maintain the metering IC 220 below the maximum operational temperature may be approximately 2J where Qc=mCpΔT (m is mass, Cp is the heat capacity, and ΔT is the difference between the maximum ambient temperature and the maximum metering IC operational temperature). Expected power consumption by the Peltier cooler 110 may range, e.g., without limitation, from 2W to 10W.

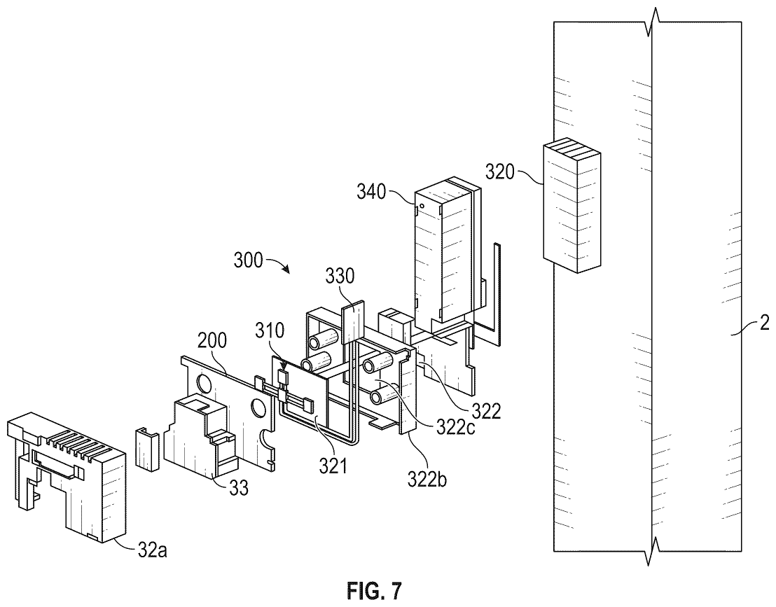

FIG. 7 is an exploded front view of an MID 30 including another exemplary novel thermal management system 300 in accordance with a non-limiting example embodiment of the disclosed concept. The MID 30 is similar to the MID 10 of FIG. 6, and thus the overlapping description is omitted for the sake of brevity. The MID 30 includes a housing, a relay 33, a sensing circuit PCB 200, an MID auxiliary portion 35, and a thermal management system 300. The housing includes a front casing 32a and a back casing 32b having a slot 32c. The thermal management system 300 includes Peltier coolers 310, a heatsink assembly, temperature sensors 140a, 140b and a power supply and controller 310. The Peltier coolers 310 are attached to the metering ICs 220 on the cold side using a TIM layer. The heatsink assembly includes a heatsink 320, an evaporator 321 and heat pipes 322. The evaporator 321 is the evaporation section of the heatsink assembly and may be, e.g., without limitation, a copper and/or aluminum plate. The evaporator 321 is attached to the hot side of the Peltier coolers 310 via a TIM layer. The heat pipes 322 are connected to the evaporator 321 at one end and the heatsink 320 at the other end (condenser side). The condenser side of the heat pipes 322 may transit through the slot 32c and below the MID auxiliary portion 35. The heatsink 320 is connected to the heat pipes 322 and absorbs the heat from the heat pipes 322 and dissipates the heat. In operation, upon detection of the ambient air temperature being above the maximum metering IC operational temperature, the power supply and controller 310 applies the DC power to the Peltier coolers 310, causing the heat to move to the hot side. The heat then is absorbed by the evaporator 321 and dissipated by the heat pipes 322 and the heatsink 320, thereby the lowering the temperature of the metering ICs 220 to below the maximum metering IC operational temperature.

FIG. 8 illustrates a partial MID 40 including another exemplary thermal management system 400 in accordance with a non-limiting, exemplary embodiment of the disclosed concept. The thermal management system 400 is similar to the thermal management system 100 of FIG. 6 except that each Peltier cooler 410 is attached to a heatsink 420 directly on the hot side. The heatsinks 420 may have the same or substantially same height and length as the Peltier coolers 410.

Accordingly, the inventive thermal management system 100, 300, 400 utilizes the available space in the meter breaker panel with minimum additional components and power consumption from the main line during the peak loads and temperatures. Further, the thermal management system 100, 300, 400 is easily integrated within the existing MIDs 10, 30, 40 and removes the heat from the metering ICs 220 without affecting any other operations of the MID 10, 30, 40. In addition, the Peltier coolers 110, 310, 410 operate only when the ambient air temperatures near the metering ICs 220 are close to the maximum metering IC operational temperature, thereby only using the main line power as needed. Furthermore, the nominal power required to operate the Peltier coolers are harvested from the main power supply (e.g., without limitation, the grid line), and thus does not require additional DC power sources to be placed within the meter breaker panel 2, thereby preserving spaces and costs. By maintaining the metering IC temperature within the maximum metering IC operational temperature, the thermal management system 100, 300, 400 improves the reliability and performance of the MID 10, 30, 40. Further, since the Peltier coolers 110, 310, 410 and the heatsink assemblies 120, 320, 420 include no moving parts, the thermal management system 100, 300, 400 improves its reliability even further.

While specific embodiments of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of disclosed concept which is to be given the full breadth of the claims appended and any and all equivalents thereof.

What is claimed is:

1. A thermal management system for use in a microgrid interconnect device (MID) having a housing, a relay structured to connect or disconnect a distributed energy resource from a primary power source, and a sensing circuit printed circuit board (PCB) including metering integrated chips (IC) structured to measure three-phase electrical energy, the thermal management system comprising:
a plurality of cooling devices connected to the metering ICs and structured to maintain metering IC temperature below maximum metering IC operational temperature;
a heatsink device connected to the cooling devices and structured to absorb and dissipate heat from the metering ICs;
a plurality of temperature sensors including ambient air temperature sensors and metering IC temperature sensors, the ambient air temperature sensors disposed proximate the metering ICs on the sensing circuit PCB and structured to measure the ambient air temperature, the metering IC temperature sensors disposed on the metering ICs and structured to measure the metering IC temperature; and
a power supply and controller connected to the cooling devices, the temperature sensors and the primary power source, the power supply and controller being structured to receive signals from the temperature sensors and cause the cooling devices to lower the metering IC temperature below the maximum metering IC operational temperature based on a signal indicating that the ambient air temperature is higher than the maximum metering IC operational temperature.

2. The thermal management system of claim 1, wherein the cooling devices are structured to maintain the metering IC temperature below the ambient air temperature.

3. The thermal management system of claim 1, wherein the cooling devices comprise Peltier coolers each having a hot side and a cold side, and wherein Peltier coolers are attached to the metering ICs on the cold side and the heatsinks on the hot side.

4. The thermal management system of claim 3, wherein the power supply and controller is disposed outside of the housing and structured to apply DC voltage to the cooling devices to remove heat from the cold side to the hot side.

5. The thermal management system of claim 3, wherein the power supply and controller is structured to harvest power from the primary power source only during peak loads and temperatures.

6. The thermal management system of claim 1, wherein the back casing includes a slot, and wherein the heatsink device comprises a heatsink attached to external surface of the back casing and bonded to the hot side of the cooling devices through the slot.

7. The thermal management system of claim 1, wherein the MID further includes an MID auxiliary part disposed external to the housing and attached to external surface of the back casing.

8. The thermal management system of claim 7, wherein the back casing includes a slot, and wherein the heatsink device comprises an evaporator structured to be connected to the hot sides of the cooling devices, a heatsink disposed external to the housing and structured to be attached to back surface of the MID auxiliary part, and heat pipes connecting the evaporator and the heatsink, the heat pipes transiting through the slot and below the MID auxiliary part.

9. The thermal management system of claim 1, wherein the heatsink device includes a plurality of heatsinks attached directly to respective cooling devices via a thermal interface material (TIM).

10. A microgrid interconnect device (MID) structured to connect or disconnect a distributed energy resource (DER) from a primary power source, comprising:
a housing having a front casing and a back casing;
a relay disposed in the front casing and structured to connect or disconnect the DER from the primary power source;
a sensing circuit printed circuit board (PCB) including metering integrated chips (IC) structured to measure three-phase electrical energy; and
a thermal management system including:
a plurality of cooling devices connected to the metering ICs and structured to maintain metering IC temperature below maximum metering IC operational temperature;
a heatsink device connected to the cooling devices and structured to absorb and dissipate heat from the metering ICs;
a plurality of temperature sensors including ambient air temperature sensors and metering IC temperature sensors, the ambient air temperature sensors disposed proximate the metering ICs on the sensing circuit PCB and structured to measure the ambient air temperature, the metering IC temperature sensors disposed on the metering ICs and structured to measure the metering IC temperature; and
a power supply and controller connected to the cooling devices, the temperature sensors and the primary power source, the power supply and controller being structured to receive signals from the temperature sensors and cause the cooling devices to lower the metering IC temperature below the maximum metering IC operational temperature based on a signal indicating that the ambient air temperature is higher than the maximum metering IC operational temperature.

11. The MID of claim 10, wherein the cooling devices are structured to maintain the metering IC temperature below the ambient air temperature.

12. The MID of claim 10, wherein the cooling devices comprise Peltier coolers each having a hot side and a cold side, and wherein Peltier coolers are attached to the metering ICs on the cold side and the heatsinks on the hot side.

13. The MID of claim 12, wherein the power supply and controller is structured to apply DC voltage to the cooling devices to remove heat from the cold side to the hot side.

14. The MID of claim 12, wherein the power supply and controller is structured to harvest power from the primary power source only during peak loads and temperatures.

15. The MID of claim 12, wherein the cooling devices are attached to the metering ICs and the heatsink device using a thermal interface material.

16. The MID of claim 10, wherein the back casing includes a slot, and wherein the heatsink device comprises a heatsink attached to external surface of the back casing and bonded to the hot side of the cooling devices through the slot.

17. The MID of claim 10, further comprising:
an MID auxiliary part disposed external to the housing and attached to external surface of the back casing.

18. The MID of claim 17, wherein the back casing includes a slot, and wherein the heatsink device comprises an evaporator structured to be connected to the hot sides of the cooling devices, a heatsink disposed external to the housing and structured to be attached to back surface of the MID auxiliary part, and heat pipes connecting the evaporator and the heatsink, the heat pipes transiting through the slot and below the MID auxiliary part.

19. The MID of claim 10, wherein the heatsink device includes a plurality of heatsinks attached directly to respective cooling devices via a thermal interface material (TIM).

20. The MID of claim 10, wherein the heatsinks each have same height and length as the cooling devices.
